(19) United States
(12) Patent Application Publication
(10) Pub. No.: US 2012/0306094 A1
(43) Pub. Date: Dec. 6, 2012

(54) SIGNAL ROUTING USING THROUGH-SUBSTRATE VIAS

(76) Inventors: Shahrazie Zainal Abu Bakar, Gelugor (MY); Fairul Hasnizam Mustaffa, Kepala Batas (MY); Azman Mohamed Eusoff, Gelugor (MY); Azam Mohammad, Bayan Baru (MY)

(21) Appl. No.: 13/153,636

(22) Filed: Jun. 6, 2011

(51) Int. Cl. H01L 23/48; H01L 21/283

(52) U.S. Cl. 257/774; 438/599; 257/E23.011; 257/E21.159

(57) ABSTRACT

The present description relates to the field of microelectronic devices and the fabrication thereof, wherein through-substrate vias are utilized to route signals between microelectronic integrated circuit components, such as transistors, resistors, capacitors, inductors, and the like, within the microelectronic devices. The through-substrate vias may be used for routing critical signals, which may include, but are not limited to, timing sensitive signal, such as clock signals and the like.

### BACKGROUND OF THE INVENTION

The present disclosure relates generally to the fabrication of microelectronic devices, and, in particular, to forming conductive trace routes for the interconnection of microelectronic integrated circuit components in the microelectronic devices.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 illustrates side cross-sectional schematic depiction of a microelectronic device having a signal trace route formed in an interconnection layer, as known in the art.

FIG. 2 illustrates a top plan view along line 2-2 of FIG. 1, as known in the art, with the dielectric layers and the substrate removed for clarity.

FIG. 3 illustrates a side cross-sectional schematic depiction of a microelectronic device having a through-substrate via signal trace route in accordance with one embodiment of the present description.

FIG. 4 illustrates a top plan view along line 4-4 of FIG. 3 in accordance with one embodiment of the present description, with the dielectric layer and the substrate removed for clarity.

FIG. 5 illustrates a process flow for a method of forming a through-substrate via signal trace route in accordance with an embodiment of the present description.

FIG. 6 is a schematic depiction of a portable device/system in accordance with one embodiment of the present description.

FIG. 7 is a schematic depiction of a computer system in accordance with one embodiment of the present description.

FIG. 8 is a schematic depiction of a system in accordance with one embodiment of the present description.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present invention. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

Embodiments of the present description relate to the field of microelectronic devices and the fabrication thereof, wherein through-substrate vias are utilized to route signals between microelectronic integrated circuit components, such as transistors, resistors, capacitors, inductors, and the like, within the microelectronic devices.

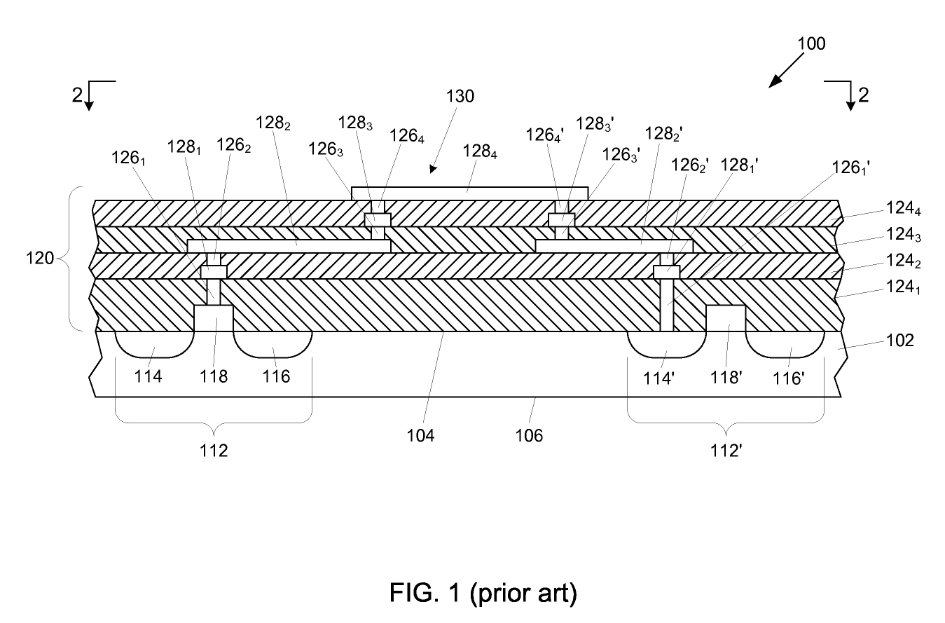

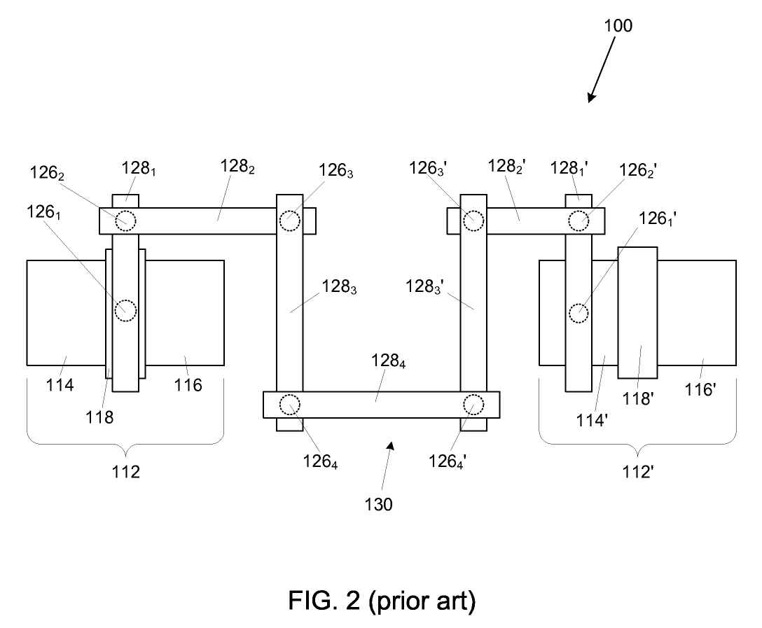

Microelectronic devices generally include interconnect layers having a plurality of dielectric layers having conductive trace routes formed thereon and therethrough. The interconnect layer may form signal routes between integrated circuits formed in and on a microelectronic substrate, and to conductive lands for external interconnect, as will be understood to those skilled in the art. FIGS. 1 and 2 illustrate a cross-sectional view and a top plan view, respectively, of an embodiment of a microelectronic device 100, as known in the art. As shown in FIG. 1, a microelectronic substrate 102 may be provided, wherein the microelectronic substrate 102 includes an active surface 104 and an opposing back surface 106 that is substantially parallel to the microelectronic substrate active surface 104. The microelectronic substrate active surface 104 may have a plurality of microelectronic integrated circuit components (shown as a first microelectronic integrated circuit component 112 and a second microelectronic integrated circuit component 112′) formed therein and/or thereon, as will be understood to those skilled in the art. The first microelectronic integrated circuit component 112 and the second microelectronic integrated circuit component 112′, for exemplary purposes, are illustrated as a first transistor and a second transistor, respectively, each having a source region (elements 114 and 114′, respectively), a drain region (elements 116 and 116′, respectively), and a gate (elements 118 and 118′, respectively).

An interconnect layer 120 may be formed adjacent the microelectronic substrate active surface 104. The interconnect layer 120 may comprise a plurality of dielectric layers with conductive traces formed on each dielectric layer with conductive vias extending through each dielectric layer to connect the conductive traces, conductive lands, and/or electrical components, on different layers. Referring to FIG. 1, the interconnect layer 120 may comprise a first dielectric layer 124₁ formed adjacent the microelectronic substrate active surface 104 with a plurality of first conductive vias extending through the first dielectric layer 124₁. FIG. 1 illustrates a first layer conductive via 126₁ contacting the first microelectronic integrated circuit component gate 118 and a first layer conductive via 126₁′ contacting the second microelectronic integrated circuit component source 114′. A plurality of first layer conductive traces may be formed on the first dielectric layer 124₁ to contact at least one first layer conductive vias. FIG. 1 illustrates a first layer conductive trace 128₁ contacting the first layer conductive via 126₁ and a first layer conductive trace 128₁′ contacting the first layer conductive via 126₁′.

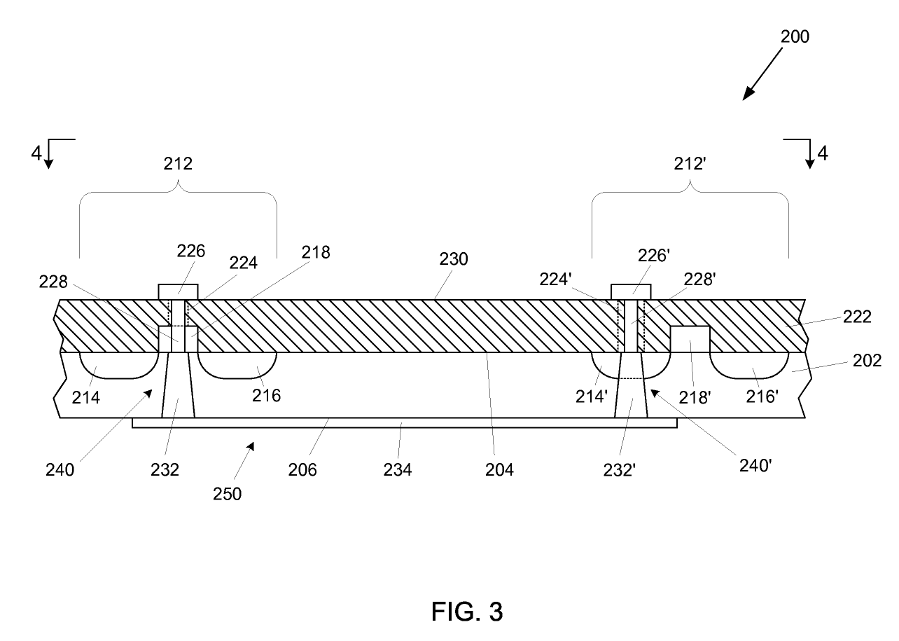

A second dielectric layer 124₂ may be formed over the first dielectric layer 124₁ and the first layer conductive traces 128₁ and 128₁′. At least one second layer conductive via may extend through the second dielectric layer 124₂ to contact at least one first layer conductive traces. FIG. 3 illustrates a second layer conductive via 126₂ contacting the first layer conductive trace 128₁ and a second layer conductive via 126₂′ contacting the first layer conductive trace 128₁′. A plurality of second layer conductive traces may be formed on the second dielectric layer 124₂ to contact at least one first layer conductive vias. FIG. 1 illustrates a second layer conductive trace 128₂ contacting the second layer conductive via 126₂ and a second layer conductive trace 128₂′ contacting the second layer conductive via 126₂′.

A third dielectric layer 124₃ may be formed over the second dielectric layer 124₂ and the second layer conductive traces 128₂ and 128₂′. At least one third layer conductive via may extend through the third dielectric layer 124₃ to contact at least one second layer conductive trace. FIG. 1 illustrates a third layer conductive via 126₃ contacting the second layer conductive trace 128₂ and a third layer conductive via 126₃′ contacting the second layer conductive trace 128₂′. A plurality of third layer conductive traces may be formed on the third dielectric layer 124₃ to contact at least one first layer conductive vias. FIG. 1 illustrates a third layer conductive trace 128₃ contacting the third layer conductive via 126₃ and a third layer conductive trace 128₃′ contacting the third layer conductive via 126₃′.

A fourth dielectric layer 124₄ may be formed over the third dielectric layer 124₃ and the third layer conductive traces 128₃ and 128₃′. At least one fourth layer conductive via may extend through the fourth dielectric layer 124₄ to contact at least one third layer conductive trace. FIG. 1 illustrates a fourth layer conductive via 126₄ contacting the third layer conductive trace 128₃ and a fourth layer conductive via 126₄′ contacting the third layer conductive trace 128₃′. A fourth layer conductive trace 128₄ may be formed on the fourth dielectric layer 124₄ to contact the fourth layer conductive via 126₄ and the fourth layer conductive via 126₄′ to interconnect the first microelectronic integrated circuit component 112 and the second microelectronic integrated circuit component 112′. Thus, the combination of the conductive vias and the conductive traces form a conductive trace route 130 between the first microelectronic integrated circuit component 112 and the second microelectronic integrated circuit component 112′.

It is understood that although four conductive trace layers and four dielectric layers are shown, the interconnect layer 120 may be any appropriate number of dielectric layers and conductive trace layers.

FIG. 2 illustrates a top plan view along line 2-2 of FIG. 1 with the dielectric layers (i.e. first dielectric layer 124₁, second dielectric layer 124₂, third dielectric layer 124₃, and fourth dielectric layer 124₄) and the microelectronic substrate 102 not shown for clarity. As it can be seen from FIGS. 1 and 2 forming an interconnection between microelectronic components (e.g. first microelectronic integrated circuit component 112 and a second microelectronic integrated circuit component 112′) can require a relatively long, convoluted path for the conductive trace routes (e.g. elements 126₁, 26₁′, 128₁, 128₁′, 126₂, 126₂′, 128₂, 128₂′, 126₃, 126₃′, 128₃, 128₃′, 126₄, 126₄′, and 128₄). This relatively long, convoluted path can present reliability issues, particularly with regard to critical signals, such as timing sensitive signals, which may require shielding to reduce noise and coupling, as will be understood to those skilled in the art.

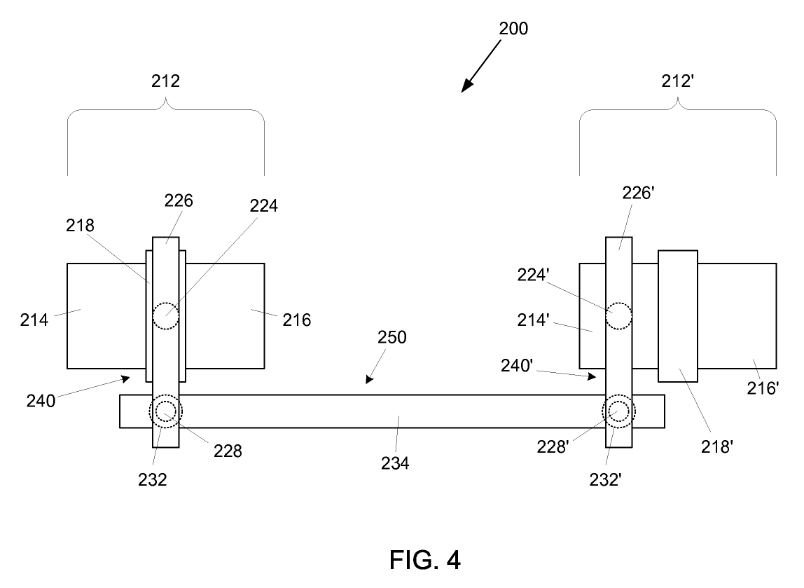

FIGS. 3 and 4 illustrate a cross-sectional view and a top plan view, respectively, of an embodiment of a microelectronic device 200, according to one embodiment of the present description. FIG. 4 illustrates an embodiment of the present description without showing the dielectric layer and the microelectronic substrate for clarity.

As shown in FIG. 3, a microelectronic substrate 202 may be provided, wherein the microelectronic substrate 202 includes an active surface 204 and an opposing back surface 206 that is substantially parallel to the microelectronic substrate active surface 204. The microelectronic substrate 202 may be any appropriate substrate including, but not limited to, a silicon-containing substrates (such as a mono-crystalline silicon wafer), a silicon-on-insulator (“SOI”) substrate, and the like. The microelectronic substrate 202 may also include a germanium substrate, a gallium arsenide substrate, an indium antimonide substrate, a lead telluride substrate, an indium arsenide substrate, an indium phosphide substrate, a gallium arsenide substrate, a gallium antimonide substrate, and the like, any of which may be combined with silicon.

The microelectronic substrate active surface 204 may have a plurality of microelectronic integrated circuit components (shown as a first microelectronic integrated circuit component 212 and a second microelectronic integrated circuit component 212′) formed therein and/or thereon, as will be understood to those skilled in the art. The first microelectronic integrated circuit component 212 and the second microelectronic integrated circuit component 212′ may be any appropriate integrated circuit device, including but not limited to transistors, resistors, capacitors, inductors, and the like. For exemplary purposes, FIGS. 3 and 4 illustrate the first microelectronic integrated circuit component 212 and the second microelectronic integrated circuit component 212′ as a first transistor and a second transistor, respectively, each having a source region (elements 214 and 214′, respectively), a drain region (elements 216 and 216′, respectively), and a gate (elements 218 and 218′, respectively), as will be understood to those skilled in the art. The microelectronic integrated circuit components 212 and 212′ may be a portion of any variety of microelectronic devices 200, including but not limited to a microprocessor (single or multi-core), a memory device, a chipset, a graphics device, an application specific integrated circuit, or the like.

At least one conductive via may be formed through the microelectronic substrate 202. Such a conductive via configuration is known as a through-substrate via (illustrated as elements 232 and 232′). To form a first through-substrate via 232 and/or the second through-substrate via 232′, at least one opening may be formed to extend from the microelectronic substrate back surface 206 through to the microelectronic substrate active surface 204. The opening(s) may be formed by any known technique, including, but not limited to, laser drilling, ion drill, etching with lithography, and the like. The openings may be filled with a conductive material to form the first through-substrate via 232 and/or the second through-substrate via 232′. The conductive material may be deposited by any known technique(s), including but limited to, plating, depositing, etching, and chemical mechanical planarization, and may be made of any appropriate conductive material, including but not limited to copper, aluminum, silver, gold, or alloys thereof.

Although the first through-substrate via 232 and the second through-substrate via 232′ are shown as being formed with a single conductive material, they may also include adhesion layers, barrier layers, and the like, as will be understood to those skilled in the art.

A dielectric layer 222 may be formed on the microelectronic substrate active surface 204 with at least one first layer conductive via extending through the dielectric layer 222 and contacting at least one microelectronic integrated circuit component adjacent the microelectronic substrate active surface 204. The dielectric layer 222 may be formed by any known technique in the art including, but not limited to, chemical vapor deposition (“CVD”), physical vapor deposition (“PVD”), and atomic layer deposition (“ALD”), and may be formed from any appropriate dielectric material, including, but is not limited to, silicon dioxide (SiO₂), silicon oxynitride (SiOₓN_{y}), and silicon nitride (Si₃N₄). The dielectric layer 222 may be planarized by any technique known in the art, including, but not limited to, wet or dry etching and chemical mechanical polishing.

At least one first conductive via may be formed through the dielectric layer 222 to extend from at least one microelectronic integrated circuit component to an upper surface 230 of the dielectric layer 222. As shown in FIG. 3, a first conductive via 224 may be formed to contact the first microelectronic integrated circuit component gate 218 and a first conductive via 224′ may be formed to the second microelectronic integrated circuit component source 214′.

At least one second conductive via may be formed through the dielectric layer 222 to extend from the through-substrate vias 232 and 232′ to the dielectric layer upper surface 230. As shown in FIG. 3, a second conductive via 228 may be formed to contact the first through-substrate via 232 and a second conductive via 228′ may be formed to contact the second through-substrate via 232′.

The first conductive vias 224 and 224′ and the second conductive vias 228 and 228′ may be fabricated by any technique known in the art, including but not limited to plating and lithography, etching, and deposition, and may be made of any appropriate conductive material, including but not limited to copper, aluminum, silver, gold, or alloys thereof.

A plurality of conductive traces may be formed on the dielectric layer upper surface 230 to connect the first conductive vias 224 and 224′ to the second conductive vias 228 and 228′. As shown in FIGS. 3 and 4, a conductive trace 226 may be formed to electrically connect the first conductive via 224 to the second conductive via 228, and a conductive trace 226′ may be formed to electrically connect the first conductive via 224′ to the second conductive via 228′. The combination of the first conductive via 224 and 224′, the corresponding second conductive vias 228 and 228′, and the corresponding conductive traces 226 and 226′ form conductive routes 240 and 240′, respectively, between the first microelectronic integrated circuit component 212 and its corresponding first through-substrate via 232, and between the second microelectronic integrated circuit component 212′ and its corresponding second through-substrate via 232′.

An interconnection conductive trace 234 may be formed on the microelectronic substrate back surface 206 to connect the first through-substrate via 232 and the second through-substrate via 232′, thereby interconnecting the first microelectronic integrated circuit component 212 and the second microelectronic integrated circuit component 212′. Thus, the combination of the conductive vias and the conductive traces form a conductive trace route 250 between the first microelectronic integrated circuit component 212 and the second microelectronic integrated circuit component 212′. The interconnection conductive trace 234 may be fabricated by any technique known in the art, including but not limited to deposition, plating, and lithography, and may be made of any appropriate conductive material, including but not limited to copper, aluminum, silver, gold, or alloys thereof.

As it can be seen from FIGS. 3 and 4 forming an interconnection between microelectronic components (e.g. first microelectronic integrated circuit component 212 and a second microelectronic integrated circuit component 212′) with the utilization of through-substrate vias (e.g. first through-substrate via 232 and the second through-substrate via 232′) may result in a comparatively shorter signal route and may obviate the need for shield with regard to critical signal conductive trace routes. This may result in improved signal efficiency and greater signal integrity, as will be understood to those skilled in the art.

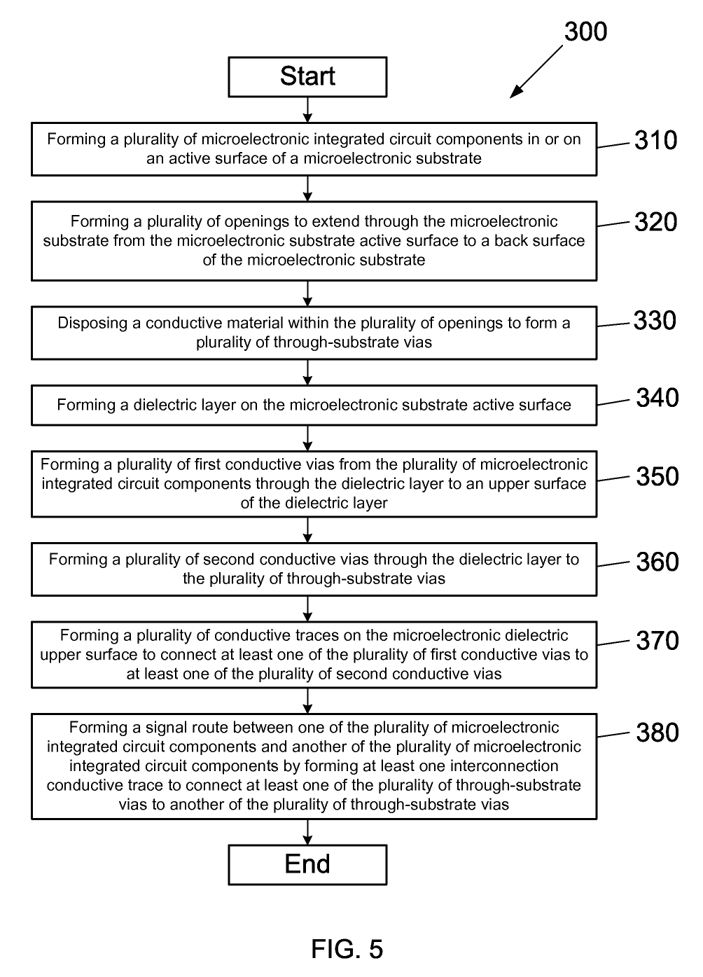

An embodiment of a process of fabricating microelectronic device having a signal trace route formed with a through-substrate via is illustrated in the flow diagram 300 of FIG. 5. As defined in block 310, a plurality of microelectronic integrated circuit components may be formed in or on (e.g. proximate) an active surface of a microelectronic substrate. A plurality of openings may be formed to extend through the microelectronic substrate from the microelectronic substrate active surface to a back surface of the microelectronic substrate, as defined in block 320. A conductive material may be disposed within the plurality of openings to form a plurality of through-substrate vias, as defined in block 330. As defined in block 340, a dielectric layer may be formed on the microelectronic substrate active surface. A plurality of first conductive vias may be formed from the plurality of microelectronic integrated circuit components through the dielectric layer to an upper surface of the dielectric layer, as defined in block 350. As defined in block 360, a plurality of second conductive vias may be formed through the dielectric layer from the dielectric layer upper surface to the plurality of through-substrate vias. As defined in block 370, a plurality of conductive traces may be formed on the microelectronic dielectric upper surface to connect at least one of the plurality of first conductive vias to at least one of the plurality of second conductive vias. As defined in block 380, at least one interconnect conductive trace may be formed on the microelectronic substrate back surface to connect at least one of the plurality of through-substrate vias to another of the plurality of through-substrate vias forming a signal route between one of the plurality of microelectronic integrated circuit components and another of the plurality of microelectronic integrated circuit components.

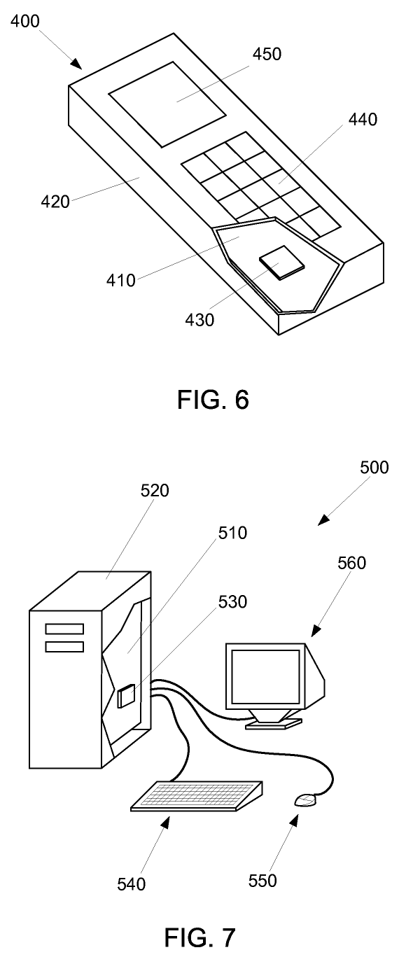

FIG. 6 illustrates an embodiment of a portable system/device 400, such as a portable computer, a mobile telephone, a digital camera, a digital music player, a web tablet/pad device, a personal digital assistant, a pager, an instant messaging device, or other devices. The portable system/device 400 may be adapted to transmit and/or receive information wirelessly, such as through a wireless local area network (WLAN) system, a wireless personal area network (WPAN) system, and/or a cellular network. The portable system/device 400 may comprise a system substrate 410 within a housing 420. The system substrate 410 may have various microelectronic devices 430 electrically coupled thereto including, but not limited to, a microelectronic device package, a microprocessor (such as a central processing units (CPUs), chipsets, graphics processing units, ASICs, or other command/data processing device), a memory device, and the like. The system substrate 410 may be attached to various peripheral devices including an input device 440, such as keypad, and a display device 450, such an LCD display. It is understood that the display device 450 may also function as the input device, if the display device 450 is touch sensitive. The embodiments of the present description may be incorporated into any of the components of the portable system/device 400, wherein through-substrate vias may be utilized to route signals between microelectronic integrated circuit components within at least one of the microelectronic devices 430.

FIG. 7 illustrates an embodiment of a computer system 500, such as a desktop computer, a server, and the like. The computer system 500 may comprise a system substrate or motherboard 510 within a housing 520. The motherboard 510 may have various microelectronic devices 530 electrically coupled thereto including, but not limited to a microprocessor (such as a central processing units (CPUs), chipsets, graphics processor, ASICs, or other command/data processing device), a memory device (such as DRAM, flash memory, a BIOS chip, a solid state drive, and the like), and any other appropriate electrical component. The system substrate or motherboard 510 may be attached to various peripheral devices including inputs devices, such as a keyboard 540 and/or a mouse 550, and a display device, such as a monitor 560. The embodiments of the present description may be incorporated into any of the components of the computer system 500, wherein through-substrate vias may be utilized to route signals between microelectronic integrated circuit components within at least one of the microelectronic devices 530.

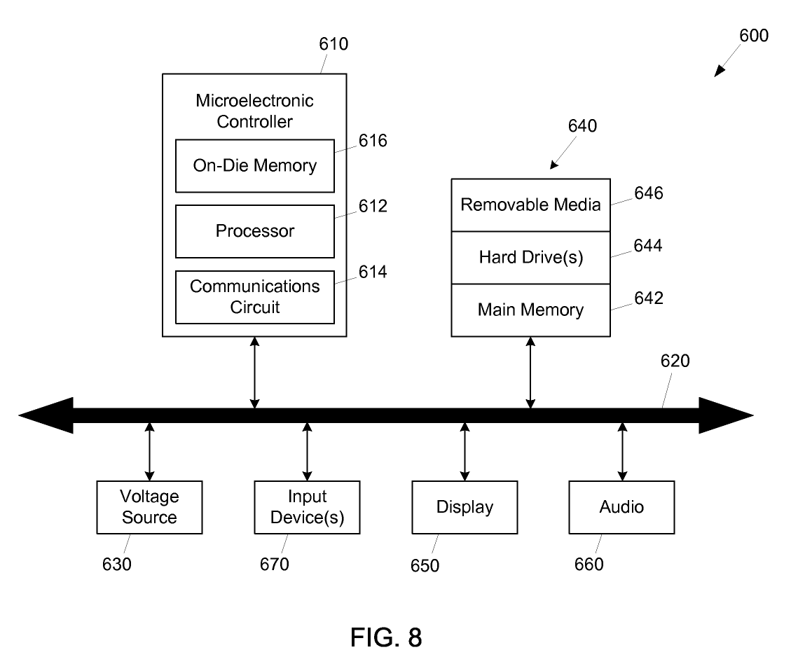

FIG. 8 is a schematic of an electronic system 600 utilizing the subject matter of the present description. The electronic system 600 may be any electronic device, including but not limited to portable system/device 400 of FIG. 6 and the computer system 500 of FIG. 7. The electronic system 600 may be adapted to transmit and/or receive information wirelessly, such as through a wireless local area network (WLAN) system, a wireless personal area network (WPAN) system, and/or a cellular network.

In an embodiment, the electronic system 600 may include a system bus 620 to electrically couple the various components of the electronic system 600. The system bus 620 may be a single bus or any combination of busses according to various embodiments. The electronic system 600 may include a voltage source 630 that provides power to a microelectronic controller 610. In some embodiments, the voltage source 630 may supply current to the microelectronic controller 610 through the system bus 620.

The microelectronic controller 610 may be electrically coupled to the system bus 620 and includes any circuit, or combination of circuits according to an embodiment. In an embodiment, the microelectronic controller 610 may include a processor 612 that can be of any type. As used herein, the processor 612 may mean any type of circuit such as, but not limited to, a microprocessor, a microcontroller, a graphics processor, a digital signal processor, or another processor. Other types of circuits that can be included in the microelectronic controller 610 are a custom circuit or an application-specific integrated circuit (ASIC), such as a communications circuit 614 for use in wireless devices such as cellular telephones, pagers, portable computers, two-way radios, and similar electronic systems. In an embodiment, the processor 612 may include on-die memory 616, such as static random-access memory (SRAM). In another embodiment, the microelectronic controller 610 may include embedded on-die memory 616, such as embedded dynamic random-access memory (eDRAM) that can be utilized as a cache memory for the processor 612. The embodiments of the present description may be incorporated into any of the components of the microelectronic controller 610, including but not limited to the processor 612, the communications circuit 614, and the on-die memory 616 (which may correspond to the microelectronic device 200 described herein), wherein through-substrate vias may be utilized to route signals between microelectronic integrated circuit components therein.

In an embodiment, the electronic system 600 also includes an external memory 640 that in turn may include one or more memory elements suitable to the particular application, such as a main memory 642 in the form of RAM or non-volatile memory, such as flash memory, one or more hard drives 644, and/or one or more drives that handle removable media 646, such as diskettes, compact disks (CDs), digital variable disks (DVDs), flash memory keys, and other removable media known in the art. The embodiments of the present description may be incorporated into any of the components of the external memory 640, including but not limited to the main memory 642, the hard drive 644, and the removable media 616 (which may correspond to the microelectronic device 200 described herein), wherein through-substrate vias may be utilized to route signals between microelectronic integrated circuit components therein.

The electronic system 600 may include input devices 670, such as a keyboard, mouse, trackball, game controller, microphone, and the like, and output (I/O) device(s), such as a display device 650 and an audio output 660.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. A microelectronic device, comprising:
a microelectronic substrate having an active surface and an opposing back surface;
a plurality of microelectronic integrated circuit components formed proximate the microelectronic substrate active surface;
a plurality of through-substrate vias extending through the microelectronic substrate from the microelectronic substrate active surface to a back surface of the microelectronic substrate;
a plurality of conductive routes between the plurality of first microelectronic integrated circuit component and the first through-substrate via;
at least one interconnection conductive trace on the microelectronic device back surface contacting at least one of the plurality of through-substrate vias and another of the plurality of through-substrate vias.

2. The microelectronic device of claim 1, wherein the plurality of through-substrate vias comprises a plurality of openings extending through the microelectronic substrate and a conductive material disposed within the plurality of openings.

3. The microelectronic device of claim 1, further including a dielectric layer proximate the microelectronic substrate active surface.

4. The microelectronic device of claim 3, wherein the plurality of conductive routes between the plurality of microelectronic integrated circuit components and the plurality of through-substrate via comprises:
a plurality of first conductive vias extending from the plurality of microelectronic integrated circuit components through the dielectric layer to an upper surface of the dielectric layer;
a plurality of second conductive vias extending through the dielectric layer from the dielectric layer upper surface to the first through-substrate via;
a plurality of conductive traces on the dielectric layer upper surface connecting the plurality of first conductive vias to a corresponding plurality of the second conductive vias.

5. A microelectronic device, comprising:
a microelectronic substrate having an active surface and an opposing back surface;
a first microelectronic integrated circuit component formed proximate the microelectronic substrate active surface;
a first through-substrate via extending through the microelectronic substrate from the microelectronic substrate active surface to a back surface of the microelectronic substrate;
a first conductive route between the first microelectronic integrated circuit component and the first through-substrate via;
a second microelectronic integrated circuit component formed proximate the microelectronic substrate active surface;
a second through-substrate via extending through the microelectronic substrate from the microelectronic substrate active surface to a back surface of the microelectronic substrate;
a second conductive route between the second microelectronic integrated circuit component and the second through-substrate via; and
an interconnection conductive trace on the microelectronic device back surface contacting the first through-substrate via and the second through-substrate via.

6. The microelectronic device of claim 5, wherein the first through-substrate via comprises an opening extending through the microelectronic substrate and a conductive material disposed within the opening.

7. The microelectronic device of claim 5, wherein the second through-substrate via comprises an opening extending through the microelectronic substrate and a conductive material disposed within the opening.

8. The microelectronic device of claim 5, further including a dielectric layer proximate the microelectronic substrate active surface.

9. The microelectronic device of claim 8, wherein the first conductive route between the first microelectronic integrated circuit component and the first through-substrate via comprises:
a first conductive via extending from the first microelectronic integrated circuit component through the dielectric layer to an upper surface of the dielectric layer;
a second conductive via extending through the dielectric layer from the dielectric layer upper surface to the first through-substrate via;
a conductive trace on the dielectric layer upper surface connecting the first conductive via to the second conductive via.

10. The microelectronic device of claim 8, wherein the second conductive route between the second microelectronic integrated circuit component and the second through-substrate via comprises:
a first conductive via extending from the second microelectronic integrated circuit component through the dielectric layer to an upper surface of the dielectric layer;
a second conductive via extending through the dielectric layer from the dielectric layer upper surface to the second through-substrate via;
a conductive trace on the dielectric layer upper surface connecting the first conductive via to the second conductive via.

11. A method, comprising:
forming a plurality of microelectronic integrated circuit components proximate an active surface of a microelectronic substrate;
forming a plurality of through-substrate vias extending through the microelectronic substrate from the microelectronic substrate active surface to a back surface of the microelectronic substrate;
forming a plurality of conductive routes between the plurality of microelectronic integrated circuit components and the plurality of through-substrate vias; and
forming at least one interconnection conductive trace on the microelectronic device back surface between at least one of the plurality of through-substrate vias to at least another of the plurality of through-substrate vias.

12. The method of claim 11, further comprising routing a critical signal from one of the plurality of microelectronic integrated circuit components to another of the plurality of microelectronic integrated circuit components through the at least one interconnection conductive trace.

13. The method of claim 12, wherein routing a critical signal from one of the plurality of microelectronic integrated circuit components to another of the plurality of microelectronic integrated circuit components through the at least one interconnection conductive trace comprises routing a timing sensitive signal from one of the plurality of microelectronic integrated circuit components to another of the plurality of microelectronic integrated circuit components through the at least one interconnection conductive trace.

14. The method of claim 13, wherein routing a timing sensitive signal from one of the plurality of microelectronic integrated circuit components to another of the plurality of microelectronic integrated circuit components through the at least one interconnection conductive trace comprises routing a clock signal from one of the plurality of microelectronic integrated circuit components to another of the plurality of microelectronic integrated circuit components through the at least one interconnection conductive trace.

15. The method of claim 11, wherein forming a plurality of through-substrate vias comprises:
forming a plurality of openings extending through the microelectronic substrate from the microelectronic substrate active surface to the microelectronic substrate back surface; and
disposing a conductive material within the plurality of openings.

16. The method of claim 11, wherein forming a plurality of conductive routes comprises:
forming a dielectric layer on the microelectronic substrate active surface;
forming a plurality of first conductive vias from the plurality of microelectronic integrated circuit components through the dielectric layer to an upper surface of the dielectric layer;
forming a plurality of second conductive vias through the dielectric layer from the dielectric layer upper surface to the plurality of through-substrate vias;
forming a plurality of conductive traces on the dielectric layer upper surface to connect at least one of the plurality of first conductive vias to at least one of the plurality of second conductive vias.

17. A system, comprising:
a system substrate; and
a microelectronic device attached to the system substrate;
wherein the microelectronic device, comprises:
a microelectronic substrate having an active surface and an opposing back surface;
a plurality of microelectronic integrated circuit components formed proximate the microelectronic substrate active surface;
a plurality of through-substrate vias extending through the microelectronic substrate from the microelectronic substrate active surface to a back surface of the microelectronic substrate;
a plurality of conductive routes between the plurality of first microelectronic integrated circuit component and the first through-substrate via;
at least one interconnection conductive trace on the microelectronic device back surface contacting at least one of the plurality of through-substrate vias and another of the plurality of through-substrate vias.

18. The system of claim 17, wherein the plurality of through-substrate vias comprises a plurality of openings extending through the microelectronic substrate and a conductive material disposed within the plurality of openings.

19. The system of claim 17, further including a dielectric layer proximate the microelectronic substrate active surface.

20. The system of claim 19, wherein the plurality of conductive routes between the plurality of microelectronic integrated circuit components and the plurality of through-substrate via comprises:
a plurality of first conductive vias extending from the plurality of microelectronic integrated circuit components through the dielectric layer to an upper surface of the dielectric layer;
a plurality of second conductive vias extending through the dielectric layer from the dielectric layer upper surface to the first through-substrate via;
a plurality of conductive traces on the dielectric layer upper surface connecting the plurality of first conductive vias to a corresponding plurality of the second conductive vias.
